(19) United States
(12) Patent Application Publication
(10) Pub. No.: US 2025/0160016 A1
(43) Pub. Date: May 15, 2025

(54) IMAGING DEVICE AND ELECTRONIC APPARATUS

(71) Applicant: SONY SEMICONDUCTOR SOLUTIONS CORPORATION, Kanagawa (JP)

(72) Inventors: Takayuki OGASAHARA, Kanagawa (JP); Michiko SAKAMOTO, Kanagawa (JP)

(73) Assignee: SONY SEMICONDUCTOR SOLUTIONS CORPORATION, Kanagawa (JP)

(21) Appl. No.: 18/722,192

(22) PCT Filed: Nov. 17, 2022
(86) PCT No.: PCT/JP2022/042704

§ 371 Date: Jun. 20, 2024

(30) Foreign Application Priority Data
Jan. 6, 2022 (JP) 2022-001095

(51) Int. Cl. H10F 39/00; H10F 39/18

(52) U.S. Cl. CPC H10F 39/8053; H10F 39/182; H10F 39/8063

(57) ABSTRACT

An imaging device according to an embodiment of the present disclosure includes: a first pixel including a first filter that transmits light of a first wavelength and a first photoelectric converter; a second pixel including a second filter that transmits light of a second wavelength and a second photoelectric converter; a third pixel including a third filter that transmits light of a third wavelength and a third photoelectric converter; a fourth pixel including a fourth filter that transmits light of the second wavelength and light of the third wavelength and a fourth photoelectric converter; a fifth pixel including a fifth filter that transmits light of the first wavelength and light of the third wavelength and a fifth photoelectric converter; and a sixth pixel including a sixth filter that transmits light of the first wavelength and light of the second wavelength and a sixth photoelectric converter.

### TECHNICAL FIELD

The present disclosure relates to an imaging device and an electronic apparatus.

### BACKGROUND ART

An imaging device including a plurality of pixel groups in which four pixels are arranged in a 2×2 matrix is proposed (PTL. 1).

### CITATION LIST

### Patent Literature

PTL 1: Japanese Unexamined Patent Application Publication No. 2019-175912

### SUMMARY OF THE INVENTION

An imaging device is demanded to be improved in performance.

It is desired to provide an imaging device excellent in performance.

An imaging device according to an embodiment of the present disclosure includes: a first pixel including a first filter that transmits light of a first wavelength and a first photoelectric converter; a second pixel including a second filter that transmits light of a second wavelength and a second photoelectric converter; a third pixel including a third filter that transmits light of a third wavelength and a third photoelectric converter; a fourth pixel including a fourth filter that transmits light of the second wavelength and light of the third wavelength and a fourth photoelectric converter; a fifth pixel including a fifth filter that transmits light of the first wavelength and light of the third wavelength and a fifth photoelectric converter; and a sixth pixel including a sixth filter that transmits light of the first wavelength and light of the second wavelength and a sixth photoelectric converter.

An electronic apparatus according to an embodiment of the present disclosure includes: an imaging device including a first pixel including a first filter that transmits light of a first wavelength and a first photoelectric converter, a second pixel including a second filter that transmits light of a second wavelength and a second photoelectric converter, a third pixel including a third filter that transmits light of a third wavelength and a third photoelectric converter, a fourth pixel including a fourth filter that transmits light of the second wavelength and light of the third wavelength and a fourth photoelectric converter, a fifth pixel including a fifth filter that transmits light of the first wavelength and light of the third wavelength and a fifth photoelectric converter, and a sixth pixel including a sixth filter that transmits light of the first wavelength and light of the second wavelength and a sixth photoelectric converter; and a signal processing section that performs signal processing on a signal outputted from the imaging device.

### BRIEF DESCRIPTION OF DRAWING

FIG. 1 is a diagram illustrating an example of a schematic configuration of an electronic apparatus according to an embodiment of the present disclosure.

FIG. 2 is a diagram illustrating an example of a schematic configuration of an imaging device according to the embodiment of the present disclosure.

FIG. 3 is a diagram illustrating an arrangement example of pixels of the imaging device according to the embodiment of the present disclosure.

FIG. 4 is a diagram illustrating an example of a circuit configuration of the pixels of the imaging device according to the embodiment of the present disclosure.

FIG. 5 is a diagram illustrating the example of the circuit configuration of the pixels of the imaging device according to the embodiment of the present disclosure.

FIG. 6 is a diagram illustrating an example of a cross-sectional configuration of the imaging device according to the embodiment of the present disclosure.

FIG. 7A is a diagram of assistance in explaining an example of a zooming process by the electronic apparatus according to the embodiment of the present disclosure.

FIG. 7B is a diagram of assistance in explaining an example of the zooming process by the electronic apparatus according to the embodiment of the present disclosure.

FIG. 7C is a diagram of assistance in explaining an example of the zooming process by the electronic apparatus according to the embodiment of the present disclosure.

FIG. 8 is a diagram illustrating an arrangement example of the pixels of the imaging device according to Modification Example 1 of the present disclosure.

FIG. 9 is a diagram illustrating an arrangement example of the pixels of the imaging device according to Modification Example 2 of the present disclosure.

FIG. 10 is a diagram illustrating an example of a cross-sectional configuration of the imaging device according to Modification Example 3 of the present disclosure.

FIG. 11 is a diagram illustrating another example of the cross-sectional configuration of the imaging device according to Modification Example 3 of the present disclosure.

FIG. 12 is a diagram illustrating an example of a cross-sectional configuration of the imaging device according to Modification Example 4 of the present disclosure.

FIG. 13 is a diagram illustrating another example of the cross-sectional configuration of the imaging device according to Modification Example 4 of the present disclosure.

FIG. 14 is a diagram illustrating an example of a cross-sectional configuration of the imaging device according to Modification Example 5 of the present disclosure.

FIG. 15A is a diagram illustrating an example of a cross-sectional configuration of the imaging device according to Modification Example 6 of the present disclosure.

FIG. 15B is a diagram illustrating another example of the cross-sectional configuration of the imaging device according to Modification Example 6 of the present disclosure.

FIG. 16 is a block diagram depicting an example of schematic configuration of a vehicle control system.

FIG. 17 is a diagram of assistance in explaining an example of installation positions of an outside-vehicle information detecting section and an imaging section.

FIG. 18 is a view depicting an example of a schematic configuration of an endoscopic surgery system.

FIG. 19 is a block diagram depicting an example of a functional configuration of a camera head and a camera control unit (CCU).

### MODES FOR CARRYING OUT THE INVENTION

In the following, some embodiments of the present disclosure are described in detail with reference to the drawings. It is to be noted that description is made in the following order.
1. Embodiment
2. Modification Examples
3. Practical Application Examples

### 1. Embodiment

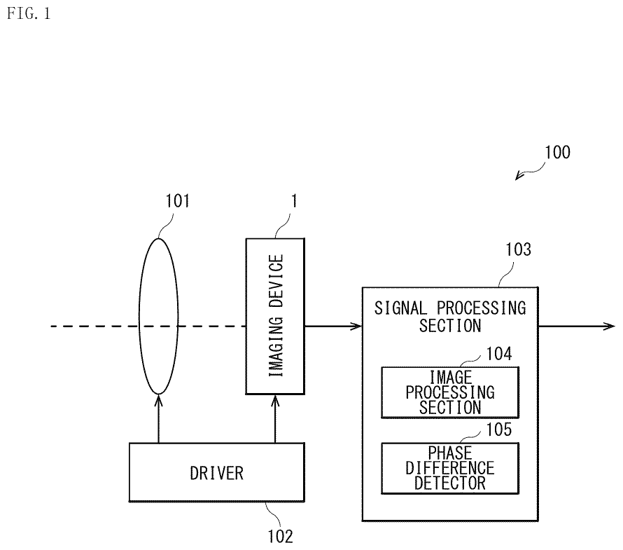

FIG. 1 is a diagram illustrating an example of a schematic configuration of an electronic apparatus according to an embodiment of the present disclosure. An electronic apparatus 100 includes an imaging device 1, an optical lens 101, a driver 102, and a signal processing section 103. The electronic apparatus 100 is usable as a variety of electronic apparatuses with an imaging function, such as a digital still camera, a video camera, and a mobile phone. The optical lens 101 lets in incoming light (imaging light) from a subject and forms an image of the subject on an imaging surface of the imaging device 1.

The imaging device 1 includes pixels including respective photoelectric converters. The pixels are arranged in a matrix. The imaging device 1 captures an image of a subject formed through the optical lens 101. The imaging device 1 includes, for example, a CMOS (Complementary Metal Oxide Semiconductor) image sensor and generates a pixel signal by photoelectrically converting received light. The imaging device 1 is configured to convert the amount of incoming light formed as an image on the imaging surface to an electric signal on a pixel-by-pixel basis and output the amount as a pixel signal.

The driver 102 includes a drive circuit and controls sections of the electronic apparatus 100. The driver 102 includes a controller and controls operations of the imaging device 1, the optical lens 101, and the like. The signal processing section 103 includes a processor and a memory (ROM, RAM, or the like) and performs various types of signal processing. The signal processing section 103 includes a signal processing circuit that processes a signal, for example, a DSP (Digital Signal Processor).

The signal processing section 103 includes an image processing section 104 a phase difference detector 105. The image processing section 104 performs signal processing on a pixel signal outputted from each of the pixels of the imaging device 1 and generates image data. The image processing section 104 includes an image data generator that generates image data. The phase difference detector 105 detects phase difference data (phase difference information) using the pixel signal outputted from a phase difference pixel of the imaging device 1. The phase difference detector 105 includes a phase difference data generator that generates the phase difference data. The phase difference detector 105 (or the driver 102) calculates a defocus amount using the phase difference data. The driver 102 drives the optical lens 101 in accordance with the calculated defocus amount. A position of the optical lens 101 in the imaging device 1 is thus adjusted to perform AF (Auto Focus).

### [Schematic Configuration of Imaging Device]

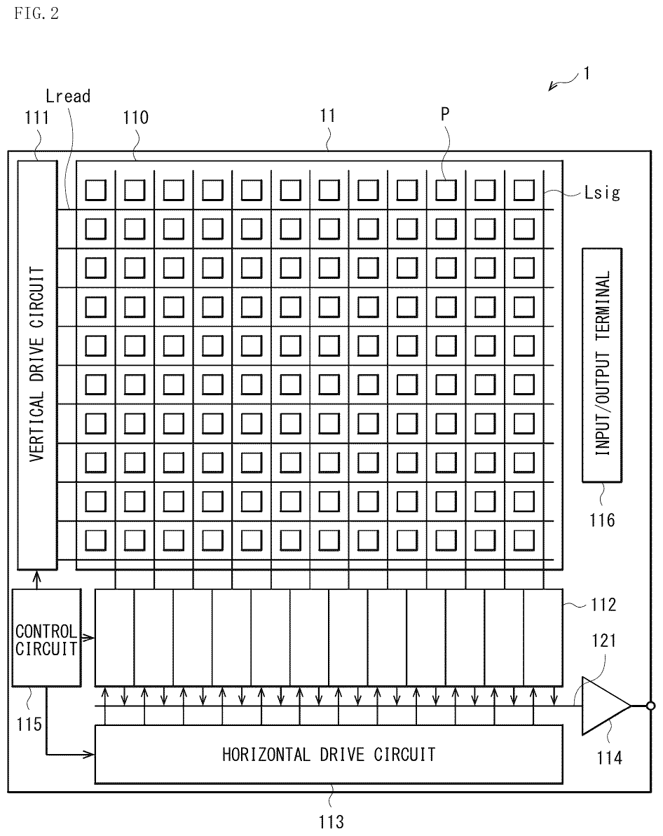

FIG. 2 is a diagram illustrating an example of a schematic configuration of an imaging device according to the embodiment. As illustrated in FIG. 2, the imaging device 1 has, as an image-capturing area, a region (a pixel section 110) in which a plurality of pixels P is two-dimensionally arranged in a matrix. The imaging device 1 includes, in a peripheral region of the pixel section 110, for example, a vertical drive circuit 111, a column signal processing circuit 112, a horizontal drive circuit 113, an output circuit 114, a control circuit 115, an input/output terminal 116, and the like.

For example, a plurality of pixel drive lines Lread is routed and a plurality of vertical signal lines Lsig is routed in the pixel section 110. The pixel drive lines Lread are configured to send drive signals (later-described signal TRG, signal SEL, signal RST, and the like) for reading signals from the pixels P.

The vertical drive circuit 111 includes a shift register, an address decoder, and the like. The vertical drive circuit 111 includes a pixel driver that derives each of the pixels P in the pixel section 110. The column signal processing circuit 112 includes, for example, an analog digital converter (ADC), a horizontal selective switch, and the like provided for each of the vertical signal lines Lsig.

Signals outputted from the individual pixels P selectively scanned by the vertical drive circuit 111 are supplied to the column signal processing circuit 112 through the vertical signal lines Lsig. The column signal processing circuit 112 performs signal processing such as CDS (Correlated Double Sampling) and AD (Analog Digital) conversion.

The horizontal drive circuit 113 includes a shift register, an address decoder, and the like and drives the individual horizontal selective switches in the column signal processing circuit 112 in sequence while scanning the horizontal selective switches. The selective scanning by the horizontal drive circuit 113 causes the signals from the individual pixels sent through the respective vertical signal lines Lsig to be outputted to a horizontal signal line 121 in sequence.

The output circuit 114 performs signal processing on the signals sequentially supplied through the horizontal signal line 121 from the individual column signal processing circuits 112 and outputs the signals. In some cases, the output circuit 114 performs, for example, only buffering or performs black level adjustment, column variation adjustment, various types of digital signal processing, and the like.

A circuit part including the vertical drive circuit 111, the column signal processing circuit 112, the horizontal drive circuit 113, the horizontal signal line 121, and the output circuit 114 may be formed in a semiconductor substrate 11 or may be installed in an external control IC. Moreover, the circuit parts may be formed in another substrate coupled through a cable or the like.

The control circuit 115 is configured to receive a clock given from outside the semiconductor substrate 11, data indicating an operation mode, or the like and output data such as internal information regarding the imaging device 1. The control circuit 115 includes a timing generator that generates a variety of timing signals. On the basis of the variety of timing signals generated by the timing generator, the control circuit 115 performs a drive control of peripheral circuits such as the vertical drive circuit 111, the column signal processing circuit 112, and the horizontal drive circuit 113. The input/output terminal 116 is configured to externally send and receive a signal.

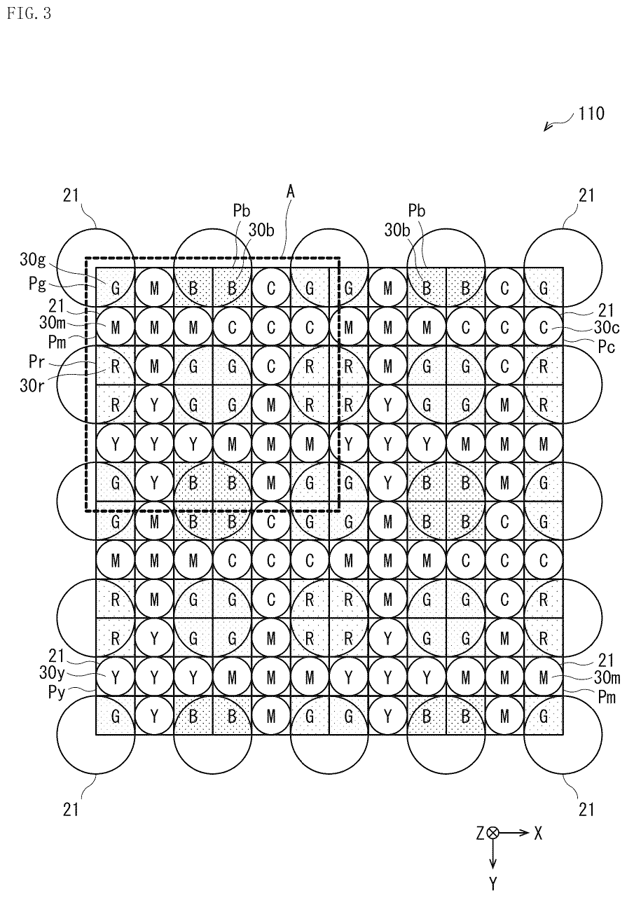

FIG. 3 is a diagram illustrating an arrangement example of the pixels of the imaging device according to the embodiment. The pixels P of the imaging device 1 each include a lens section 21 that collects light and a color filter 30 (in FIG. 3, the color filters 30r, 30g, 30b, 30c, 30m, and 30y). The lens section 21 includes an optical member called on-chip lens and is provided above the color filter 30 for each pixel P or for a plurality of pixels P. Light from a subject enters the lens section 21 through the above-described optical lens 101 (see FIG. 1). It is to be noted that an incident direction of light from a subject is defined as a Z-axis direction, a right-and-left direction in the plane of paper orthogonal to the Z-axis direction is defined as an X-axis direction, and an up-and-down direction in the plane of paper orthogonal to the Z-axis and the X-axis is defined as a Y-axis direction as illustrated in FIG. 3. Regarding the drawings hereinbelow, a direction is represented with reference to the directions of the arrows in FIG. 3 in some cases.

The color filter 30 selectively transmits, within incoming light, light of a specific wavelength band. The plurality of pixels P provided in the pixel section 110 of the imaging device 1 includes a plurality of pixels Pr, a plurality of pixels Pg, a plurality of pixels Pb, a plurality of pixels Pc, a plurality of pixels Pm, and a plurality of pixels Py as illustrated in FIG. 3. In the pixel section 110, 6×6 pixels including a plurality of pixels Pr, a plurality of pixels Pg, a plurality of pixels Pb, a plurality of pixels Pc, a plurality of pixels Pm, and a plurality of pixels Py are repeatedly arranged as in an example identified by broken lines A in FIG. 3. The pixels each include, for example, a photodiode PD as a photoelectric converter.

The pixels Pr are pixels provided with the respective color filters 30r that transmit red (R) light. The color filters 30r transmit light of a wavelength band of red. The photoelectric converters of the pixels Pr receive light of a wavelength of red and perform photoelectric conversion. The pixels Pg are pixels provided with the respective color filters 30g that transmit green (G) light. The color filters 30g transmit light of a wavelength band of green. The photoelectric converters of the pixels Pg receive light of a wavelength of green and perform photoelectric conversion.

The pixels Pb are pixels provided with the respective color filters 30b that transmit blue (B) light. The color filters 30b transmit light of a wavelength band of blue. The photoelectric converters of the pixels Pb receive light of a wavelength of blue and perform photoelectric conversion. The pixels Pc are pixels provided with the respective color filters 30c that transmit cyan (Cy) light. The color filters 30c transmit light of a wavelength band of cyan. Cyan is in a complementary relationship with red. The color filters 30c may transmit light of the wavelength band of green and light of the wavelength band of blue. The photoelectric converters of the pixels Pc receive light of a wavelength of cyan and perform photoelectric conversion.

The pixels Pm are pixels provided with the respective color filters 30m that transmit magenta (Mg) light. The color filters 30m transmit light of a wavelength band of magenta. Magenta is in a complementary relationship with green. The color filters 30m may transmit light of the wavelength band of red and light of the wavelength band of blue. The photoelectric converters of the pixels Pm receive light of a wavelength of magenta and perform photoelectric conversion. The pixels Py are pixels provided with the respective color filters 30y that transmit yellow (Ye) light. The color filters 30y transmit light of a wavelength band of yellow. Yellow is in a complementary relationship with blue. The color filters 30y may transmit light of the wavelength band of red and light of the wavelength band of green. The photoelectric converters of the pixels Py receive light of a wavelength of yellow and perform photoelectric conversion.

The pixels Pr, the pixels Pg, and the pixels Pb generate a pixel signal with an R component, a pixel signal with a G component, and a pixel signal with a B component, respectively. This makes it possible for the imaging device 1 to obtain RGB pixel signals. Moreover, the pixels Pc, the pixels Pm, and the pixels Py generate a pixel signal with a Cy component, a pixel signal with a Mg component, and a pixel signal with a Ye component, respectively. This makes it possible for the imaging device 1 to obtain CMY pixel signals. As seen from the above, primary-color pixels, i.e., the pixels Pr, the pixels Pg, and the pixels Pb, and complementary-color pixels, i.e., the pixels Pc, the pixels Pm, and the pixels Py, are arranged in the pixel section 110 of the imaging device 1. This makes it possible to obtain both an RGB image and a CMY image by performing imaging once to enable a high color reproducibility.

In the imaging device 1, the pixels Pr, the pixels Pg, and the pixels Pb are each arranged in a unit of 2×2 pixels as illustrated in FIG. 3. It can also be said that the pixels Pr, the pixels Pg, and the pixels Pb are each periodically arranged in two rows and two columns. In the pixel section 110, adjacent four of the pixels Pr, adjacent four of the pixels Pg, and adjacent four of the pixels Pb are repeatedly arranged. It can also be said that the four pixels Pr, the four pixels Pg, and the four pixels Pb are arranged in accordance with the Bayer arrangement.

For the pixels including the primary (RGB) color filters 30, i.e., the pixels Pr, the pixels Pg, and the pixels Pb, the lens section 21 is provided per four pixels. For example, one lens section 21 is disposed with respect to 2×2 pixels including adjacent four of the pixels Pr as illustrated in FIG. 3. The photoelectric converters of the four pixels Pr individually receive light passing through different regions from one another in the optical lens 101 to perform pupil division. This makes it possible to obtain phase difference information using the pixel signals outputted from the individual pixels Pr to enable phase difference AF (Auto Focus) to be performed.

Moreover, one lens section 21 is disposed with respect to four of the pixels Pg as illustrated in FIG. 3. This makes it possible to obtain phase difference data (phase difference information) using the pixel signals outputted from the individual pixels Pg to enable the phase difference AF to be performed. Moreover, one lens section 21 is disposed with respect to four of the pixels Pb. This makes it possible to obtain phase difference data using the pixel signals outputted from the individual pixels Pb to enable the phase difference AF to be performed.

The pixels Pr, the pixels Pg, and the pixels Pb are also phase difference pixels that are able to output signals used for phase difference detection. The phase difference pixels arranged in a unit of 2×2 pixels are repeatedly provided all over the imaging surface of the imaging device 1, that is, in the whole pixel section 110. This makes it possible to obtain phase difference data from all over the imaging surface of the imaging device 1 and perform a highly accurate autofocus. Therefore, it is possible to improve the imaging quality of an image.

For the pixels including the complementary (CMY) color filters 30, i.e., the pixels Pc, the pixels Pm, and the pixels Py, the lens section 21 is provided for each pixel. One lens section 21 is disposed with respect to each of the pixels Pc. Moreover, one lens section 21 is disposed with respect to each of the pixels Pm and one lens section 21 is disposed with respect to each of the pixels Py. The complementary-color pixels Pc, pixels Pm, and pixels Py are arranged between adjacent ones of the primary-color pixels. As illustrated in FIG. 3, five of the pixels Pc are arranged in a cross. Moreover, five of the pixels Pm are arranged in a cross and five of the pixels Py are also arranged in a cross.

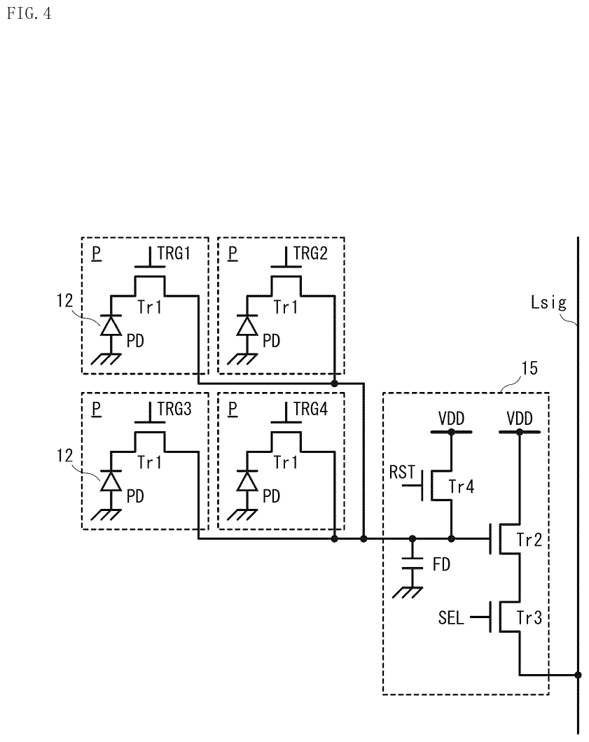

The imaging device 1 is provided with a later-described reading circuit (see FIG. 4) per pixels of the same color arranged in a 2×2 unit (see FIG. 4). The reading circuit includes an amplifier transistor, a reset transistor, and the like and outputs a pixel signal based on a charge photoelectrically converted by the photoelectric converter. The 2×2 pixels including adjacent four of the pixels Pr share one reading circuit. Moreover, the 2×2 pixels including adjacent four of the pixels Pg share one reading circuit and the 2×2 pixels including adjacent four of the pixels Pb share one reading circuit. As seen from the above, as for the RGB pixels, one reading circuit is provided per 2×2 pixels of the same color. A pixel signal from each of the 2×2 pixels is to be read by causing the reading circuit to operate by time-sharing. It is also possible to read a pixel signal in which the respective signals from the 2×2 pixels are added.

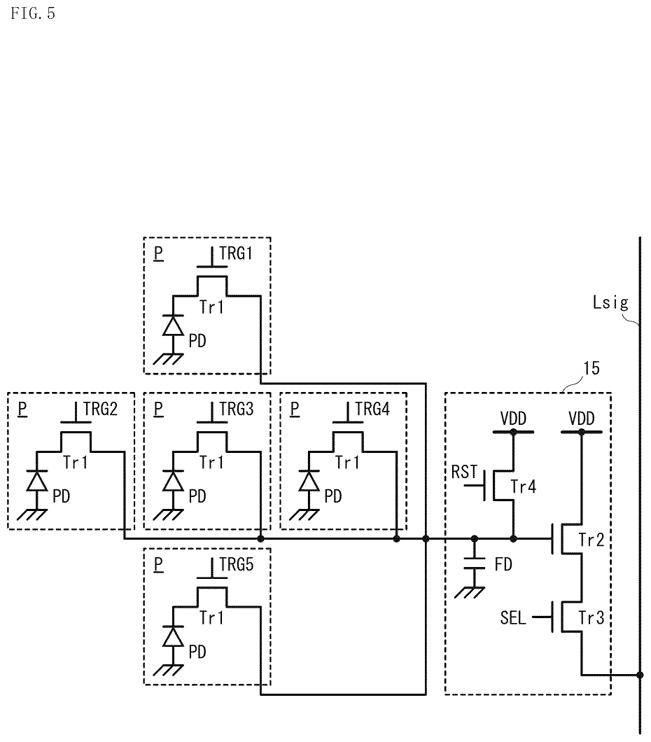

The imaging device 1 is also provided with a later-described reading circuit (see FIG. 5) per pixels of the same color arranged in a cross. Five of the pixels Pc arranged in a cross share one reading circuit. Moreover, five of the pixels Pm arranged in a cross share one reading circuit and five of the pixels Py arranged in a cross share one reading circuit. As seen from the above, as for the CMY pixels, one reading circuit is provided per pixels of the same color arranged in a cross. A pixel signal from each of the five pixels is to be read by causing the reading circuit to operate by time-sharing. It is also possible to read a pixel signal in which the respective signals from the five pixels are added.

FIG. 4 is a diagram illustrating an example of a circuit configuration of the 2×2 pixels of the imaging device according to the embodiment. The above-described 2×2 pixels (in FIG. 3, four of the pixels Pr, four of the pixels Pg, or four of the pixels Pb) each have the circuit configuration illustrated in FIG. 4. As illustrated in FIG. 4, the four of the pixels P each have a photoelectric converter 12 and a transfer transistor Tr1.

The photoelectric converter 12 includes a photodiode (PD) and converts incoming light to charge. The photoelectric converter 12 generates a charge corresponding to the amount of received light by performing photoelectric conversion. The transfer transistor Tr1 is electrically coupled to the photoelectric converter 12. The transfer transistor Tr1 is to be controlled in accordance with the signal TRG, transferring the charge photoelectrically converted and accumulated by the photoelectric converter 12 to a floating diffusion (FD).

The FD includes a charge retainer and retains the transferred charge. It can be said that the FD includes a charge accumulator that accumulates the charge transferred from the photodiode PD. The FD accumulates the transferred charge and converts the charge to a voltage corresponding to a capacity of the FD. In the example illustrated in FIG. 4, on/off of the respective transfer transistors Tr1 of the four pixels P is to be controlled in accordance with signals different from one another (in FIG. 4, signal TRG1 to signal TRG4).

A reading circuit 15 includes, by way of example, an amplifier transistor Tr2, a selection transistor Tr3, and a reset transistor Tr4. A gate of amplifier transistor Tr2 is coupled to the FD and the voltage converted by the FD is to be inputted thereto. The amplifier transistor Tr2 generates a signal based on the charge accumulated in the FD, that is, a pixel signal based on the voltage of the FD. The pixel signal is an analog signal based on the photoelectrically converted charge.

The selection transistor Tr3 is to be controlled in accordance with the signal SEL, outputting the pixel signal from the amplifier transistor Tr2 to the vertical signal line Lsig. The selection transistor Tr3 may control an output timing of the pixel signal. The reset transistor Tr4 is to be controlled in accordance with the signal RST and may reset the charge accumulated in the FD and reset the voltage of the FD.

It is to be noted that the above-described five of the pixels arranged in a cross share one reading circuit 15 as in the example illustrated in FIG. 5. Five of the pixels Pc, five of the pixels Pm, or five of the pixels Py arranged in a cross each have a circuit configuration illustrated in FIG. 5. In the example illustrated in FIG. 5, on/off of the respective transfer transistors Tr1 of the five pixels P is to be controlled in accordance with signals different from one another (in FIG. 5, the signal TRG1 to a signal TRG5).

The pixel signal outputted from the reading circuit 15 is to be inputted to the above-described column signal processing circuit 112 (see FIG. 2) through the vertical signal line Lsig. It is to be noted that the selection transistor Tr3 may be provided between a power line to which a power voltage VDD is to be applied and the amplifier transistor Tr2. Moreover, the selection transistor Tr3 may be omitted, if necessary.

### [Configuration of Pixel]

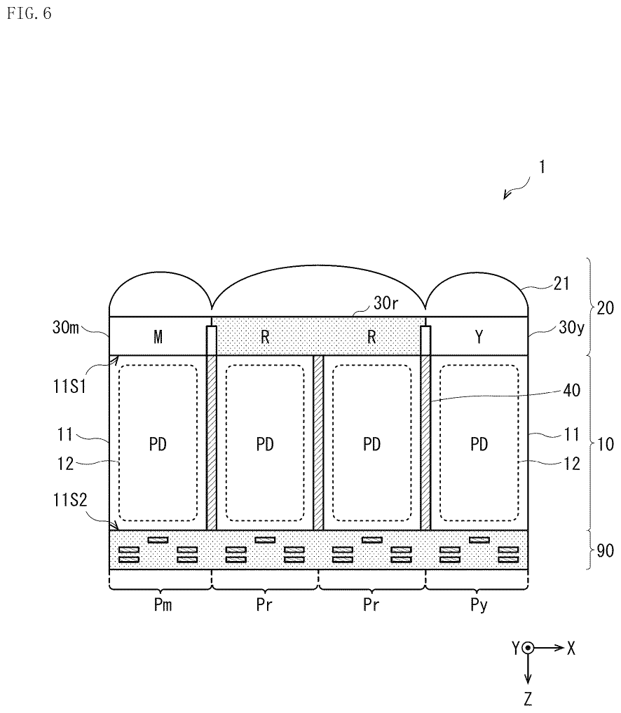

FIG. 6 is a diagram illustrating an example of a cross-sectional configuration of the imaging device according to the embodiment. The imaging device 1 includes a light receiver 10, a light guide 20, and a multilayered wiring layer 90 that are stacked in the Z-axis direction. The light receiver 10 includes the semiconductor substrate 11 having opposite first surface 11S1 and second surface 11S2. The light guide 20 is provided on the side of the first surface 11S1 of the semiconductor substrate 11 and the multilayered wiring layer 90 is provided on the side of the second surface 11S2 of the semiconductor substrate 11. It can also be said that the light guide 20 is provided on the side where light from the optical lens 101 (see FIG. 1) is to enter and the multilayered wiring layer 90 is provided on the opposite side to the side where light is to enter. The imaging device 1 is a so-called back-illuminated imaging device.

The semiconductor substrate 11 includes, for example, a silicon substrate. The photoelectric converter 12 includes a photodiode (PD) and has a pn junction in a predetermined region of the semiconductor substrate 11. A plurality of photoelectric converters 12 is formed to be embedded in the semiconductor substrate 11. The plurality of photoelectric converters 12 is provided in the light receiver 10 along the first surface 11S1 and the second surface 11S2 of the semiconductor substrate 11.

The multilayered wiring layer 90 includes, for example, a plurality of wiring layers stacked with an interlayer insulating layer in between. The wiring layers of the multilayered wiring layer 90 include, for example, aluminum (Al), copper (Cu), or tungsten (W). In addition to the above, the wiring layers may include polysilicon (Poly-Si). The interlayer insulating layer includes, for example, a monolayer film of at least one of silicon oxide (SiOx), silicon nitride (SiNx), or silicon oxynitride (SiOxNy) or a stacked layer of two or more of them.

The above-described transfer transistor Tr1 and reading circuit 15 are formed in the semiconductor substrate 11 and the multilayered wiring layer 90. Moreover, for example, the above-described vertical drive circuit 111, column signal processing circuit 112, horizontal drive circuit 113, output circuit 114, control circuit 115, input/output terminal 116, and the like are formed in the semiconductor substrate 11 and the multilayered wiring layer 90.

The light guide 20 includes the above-described lens section 21 and color filter 30 and guides light entering from above in FIG. 6 toward the light receiver 10. FIG. 6 illustrates the pixel Pm including the color filter 30m of Mg (magenta), the pixel Pr including the color filter 30r of R (red), and the pixel Py including the color filter 30y of Y (yellow). The light guide 20 is stacked on the light receiver 10 in a thickness direction orthogonal to the first surface 11S1 of the semiconductor substrate 11.

A separator 40 is provided between adjacent ones of the photoelectric converters 12 to separate the photoelectric converters 12 from each other. It can also be said that since having a trench structure provided at a boundary between adjacent ones of the pixels P, the separator 40 is an inter-pixel separator or an inter-pixel partition. The separator 40 may be formed to reach the second surface 11S2 of the semiconductor substrate 11 as illustrated in FIG. 6.

It is to be noted that the imaging device 1 may include an antireflection film and a fixed charge film between the color filters 30 and the photoelectric converters 12. The fixed charge film is a film having a fixed charge and reduces occurrence of dark current in an interface of the semiconductor substrate 11. The above-described light guide 20 may include the antireflection film and the fixed charge film.

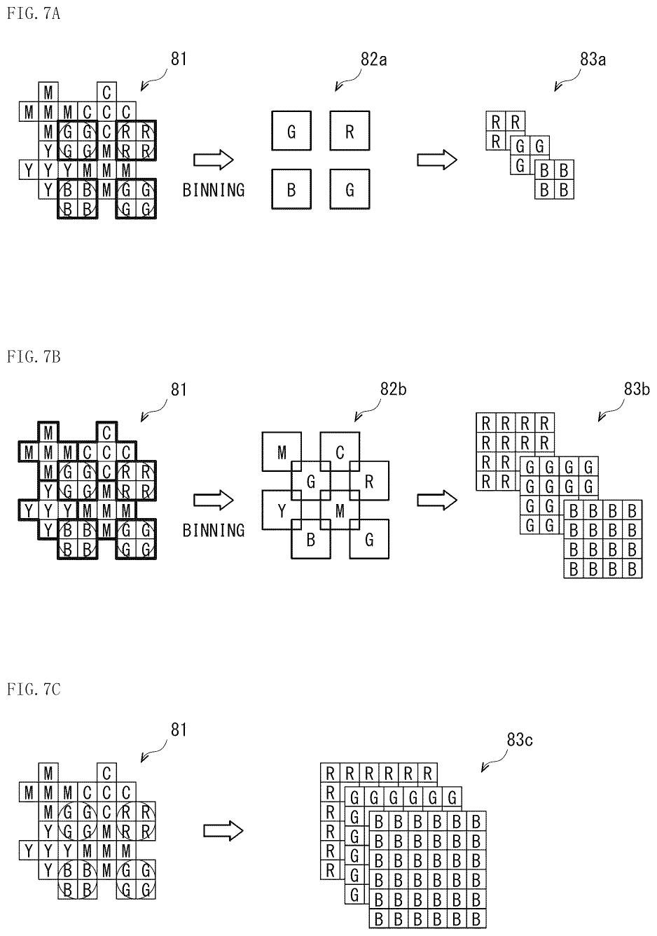

Next, description will be made on an example of a zooming process by the electronic apparatus 100 with reference to FIG. 7A to FIG. 7C. FIG. 7A illustrates a case where an enlargement factor (a magnification) of digital zoom (electronic zoom) is “small.” FIG. 7B illustrates a case where the enlargement factor of digital zoom is “middle” and FIG. 7C illustrates a case where the enlargement factor of digital zoom is “large.”

In the case where the enlargement factor is “small”, the image processing section 104 of the signal processing section 103 performs a binning process on RAW image data 81 including the pixel signal of each of the pixels outputted from the imaging device 1 after performing white balance adjustment. In this case, as indicated by bold lines in the RAW image data 81 in FIG. 7A, the image processing section 104 performs the binning process on, within the RAW image data 81, the pixel signals of 2×2 pixels, or four pixels of the same color.

During the binning process, the image processing section 104 adds the respective pixel signals of 2×2 pixels, or four pixels Pr. The image processing section 104 adds the respective pixel signals of 2×2 pixels, or four pixels Pg. The image processing section 104 also adds the respective pixel signals of 2×2 pixels, or four pixels Pb. The image processing section 104 applies the binning process on the RAW image data 81 in this manner, thereby generating image data 82a as illustrated in FIG. 7A.

The image processing section 104 then performs signal processing using the image data 82a, thereby generating RGB image data 83a as illustrated in FIG. 7A. In this case, the image processing section 104 performs an interpolating process on the image data 82a, thereby generating the RGB image data 83a containing the pixel signals of three color components, RGB, on a pixel-by-pixel basis.

As seen from the above, in the case where the enlargement factor is “small”, the binning process is to be performed on, within the RAW image data 81, the pixel signals of the RGB pixels and the RGB image data 83a is to be generated using the pixel signals of RGB subjected to the binning process. By virtue of performing the binning process, it is possible to generate the RGB image data 83a with reduced noise and cause an image with a “small” enlargement factor to be displayed using the RGB image data 83a.

In the case where the enlargement factor is “middle,” the image processing section 104 performs the binning process on the RAW image data 81 after performing the white balance adjustment. In this case, as indicated by bold lines in the RAW image data 81 in FIG. 7B, the image processing section 104 performs the binning process on, within the RAW image data 81, the pixel signals of 2×2 pixels, or four pixels of the same color. The image processing section 104 also performs the binning process on, within the RAW image data 81, the pixel signals of five pixels of the same color arranged in a cross.

During the binning process, the image processing section 104 adds the respective pixel signals of 2×2 pixels, or four pixels Pr. The image processing section 104 adds the respective pixel signals of 2×2 pixels, or four pixels Pg. The image processing section 104 also adds the respective pixel signals of 2×2 pixels, or four pixels Pb.

The image processing section 104 further adds the respective pixel signals of five pixels Pc arranged in a cross. The image processing section 104 adds the respective pixel signals of five pixels Pm arranged in a cross. The image processing section 104 also adds the respective pixel signals of five pixels Py arranged in a cross. The image processing section 104 performs the binning process on the RAW image data 81 in this manner, thereby generating image data 82b as illustrated in FIG. 7B.

The image processing section 104 then performs signal processing using the image data 82b, thereby generating RGB image data 83b as illustrated in FIG. 7B. In this case, the image processing section 104 performs, for example, the interpolating process on the image data 82b, thereby calculating the pixel signals of the six color components, RGB and CMY, on a pixel-by-pixel basis. The image processing section 104 also performs matrix computation on the pixel signals of the six color components, RGB and CMY, thereby generating the RGB image data 83b containing the pixel signals of the three color components, RGB, on a pixel-by-pixel basis as illustrated in FIG. 7B. Performing the interpolating process and the matrix computation makes it possible to generate the highly sensitive RGB image data 83b.

As seen from the above, in the case where the enlargement factor is “middle”, the binning process is to be performed on, within the RAW image data 81, both the pixel signals of the RGB pixels and the pixel signals of the CMY pixels and the RGB image data 83b is to be generated using the pixel signals of RGB and the pixel signals of CMY subjected to the binning process. This makes it possible to acquire the RGB image data 83b higher in resolution than the RGB image data 83a as in the case where the enlargement factor is “small” as illustrated in FIG. 7B. The use of the RGB image data 83b makes it possible to display, as an image of a “middle” enlargement factor, an image higher in resolution than an image of a “small” enlargement factor.

In the case where the enlargement factor is “large,” the image processing section 104 generates RGB image data 83c using the RAW image data 81 after performing the white balance adjustment. In this case, the image processing section 104 performs, for example, the interpolating process on the RAW image data 81 subjected to the white balance adjustment, thereby calculating the pixel signals of the six color components, RGB and CMY, on a pixel-by-pixel basis. The image processing section 104 also performs matrix computation on the pixel signals of the six color components, RGB and CMY, thereby generating the RGB image data 83c containing the pixel signals of the three color components, RGB, on a pixel-by-pixel basis as illustrated in FIG. 7C. Performing the interpolating process and the matrix computation process makes it possible to generate the highly sensitive RGB image data 83c.

As seen from the above, in the case where the enlargement factor is “large”, the RGB image data 83c is to be generated using the pixel signals of the RGB pixels and the pixel signals of the CMY pixels contained in the RAW image data 81 without performing the binning process. This makes it possible to generate the RGB image data 83c higher in resolution than the RGB image data 83b as in the case where the enlargement factor is “middle” as illustrated in FIG. 7C. The use of the RGB image data 83c makes it possible to display an image with a full resolution. Therefore, the electronic apparatus 100 according to the present embodiment enables gradually changing the resolution of an image in accordance with the enlargement factor to enable seamless digital zoom.

### Workings and Effects

The imaging device 1 according to the present embodiment includes: a first pixel (for example, the pixel Pr) including a first filter that transmits light of a first wavelength and a first photoelectric converter; a second pixel (the pixel Pg) including a second filter that transmits light of a second wavelength and a second photoelectric converter; a third pixel (the pixel Pb) including a third filter that transmits light of a third wavelength and a third photoelectric converter; a fourth pixel (the pixel Pc) including a fourth filter that transmits the light of the second wavelength and the third wavelength and a fourth photoelectric converter; a fifth pixel (the pixel Pm) including a fifth filter that transmits the light of the first wavelength and the third wavelength and a fifth photoelectric converter; and a sixth pixel (the pixel Py) including a sixth filter that transmits the light of the first wavelength and the second wavelength and a sixth photoelectric converter.

The imaging device 1 according to the present embodiment is provided with the pixel Pr, the pixel Pg, the pixel Pb, the pixel Pc, the pixel Pm, and the pixel Py. This makes it possible to obtain pixel signals of RGB and pixel signals of CMY. Both an RGB image and a CMY image are obtainable by performing imaging once to enable a high color reproducibility.

Next, description will be made on modification examples of the present disclosure. Hereinbelow, the same reference sign is used to refer to a component similar to that of the above-described embodiment and the description thereof is omitted as appropriate.

### 2. Modification Examples

### 2-1. Modification Example 1

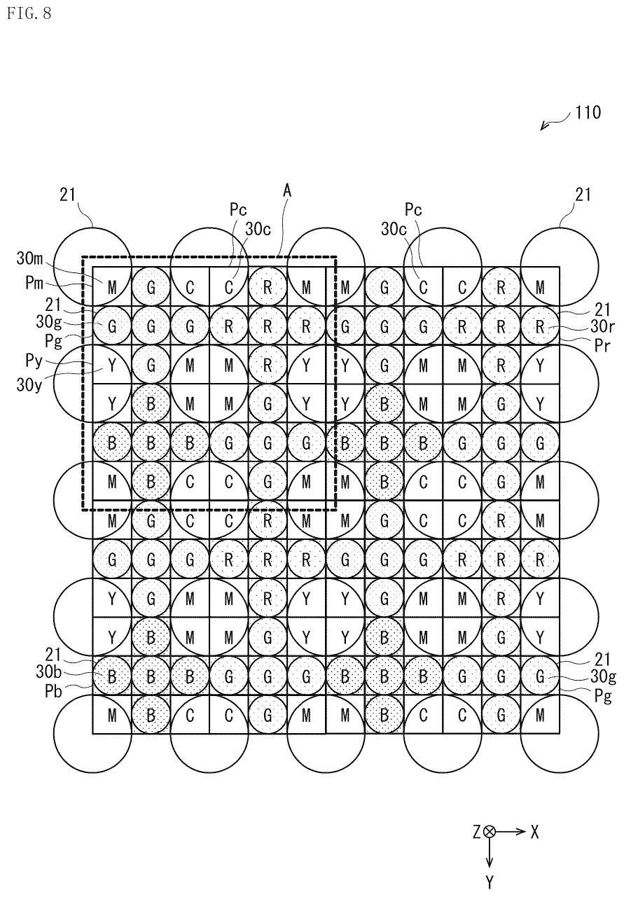

In the above-described embodiment, the arrangement example of the pixels is described but the arrangement of the pixels is not limited thereto. The complementary color pixels may be arranged in a unit of 2×2 pixels. As illustrated in FIG. 8, the pixels Pc, the pixels Pm, and the pixels Py may each be arranged in a unit of 2×2 pixels, while the pixels Pr, the pixels Pg, and the pixels Pb may each be arranged in a cross. In the example illustrated in FIG. 8, as for the pixels including the complementary color filters 30, i.e., the pixels Pc, the pixels Pm, and the pixels Py, the lens section 21 is provided per four of the pixels. Phase difference information is thus obtainable by using pixel signals outputted from four of the pixels Pc, four of the pixels Pm, or four of the pixels Py to enable the phase difference AF to be performed.

In the imaging device 1 according to the present modification example, the pixels Pc, the pixels Pm, and the pixels Py are also phase difference pixels. In a case of the present modification example, the phase difference pixels are also repeatedly provided all over the imaging surface of the imaging device 1, that is, in the whole pixel section 110. This makes it possible to obtain phase difference data from all over the imaging surface of the imaging device 1 and perform a highly accurate autofocus. Therefore, it is possible to improve the imaging quality of an image.

In the case of the present modification example, both an RGB image and a CMY image are also obtainable by performing imaging once to enable a high color reproducibility. Moreover, it is possible to perform a zooming process similar to that in the case of the above-described embodiment. This makes it possible to gradually change the resolution of an image in accordance with the enlargement factor to enable seamless digital zoom. As seen from the above, in the case of the present modification example, it is also possible to produce effects similar to those of the electronic apparatus of the above-described embodiment.

### 2-2. Modification Example 2

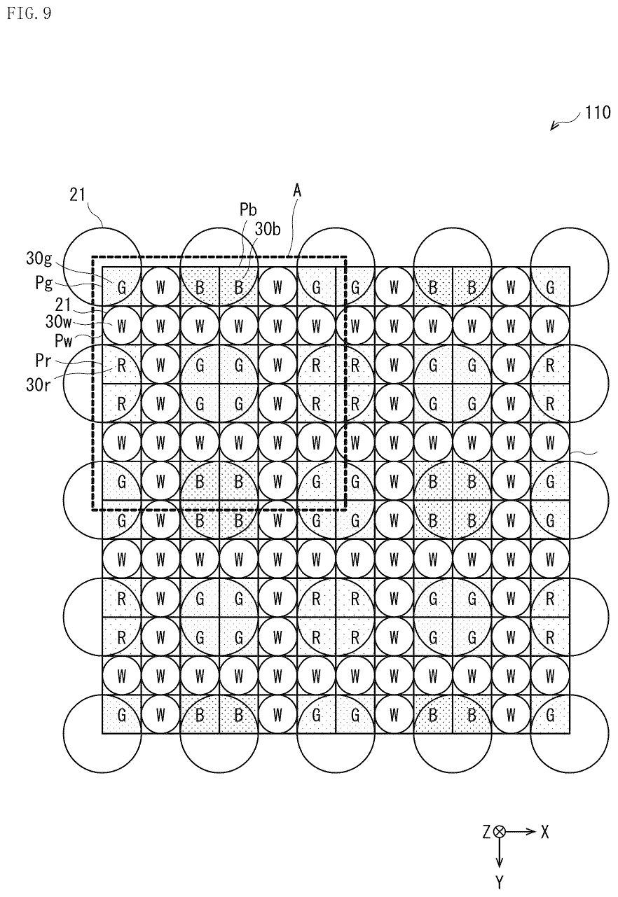

The filters provided in the pixels P are not limited to the above-described examples. For example, a color filter corresponding to W (white), that is, a filter that transmits incoming light of all wavelength bands, may be arranged. By way of example, the RGB pixels may be repeatedly arranged in a unit of 2×2 pixels, while pixels Pw including W (white) color filters 30w may be arranged in a cross as illustrated in FIG. 9. Moreover, for example, color filters of orange or wide green may be arranged.

### 2-3. Modification Example 3

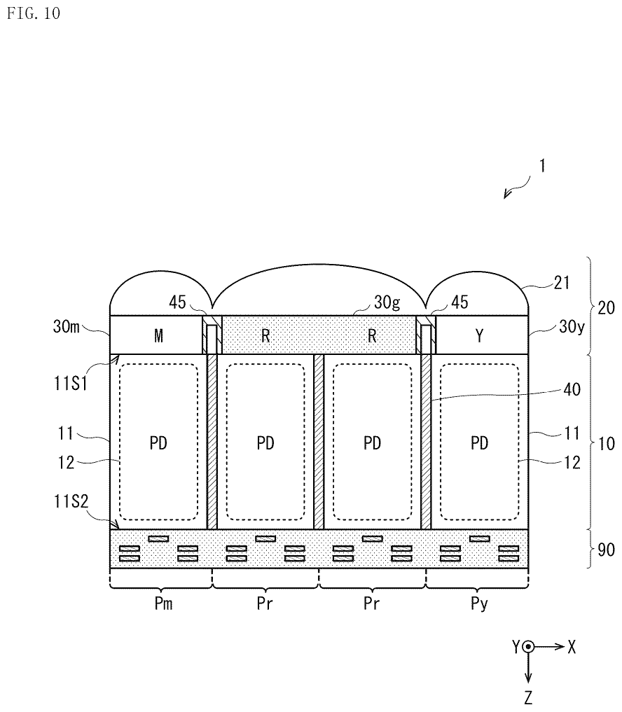

FIG. 10 is a diagram illustrating an example of a cross-sectional configuration of an imaging device according to Modification Example 3. The imaging device 1 includes a first light guide member 45 provided between adjacent ones of the color filters 30. The first light guide member 45 has a lower refractive index than a surrounding medium. The first light guide member 45, for example, includes an oxide film or has a void (a gap). The first light guide member 45A changes a travel direction of incoming light depending on a difference in refractive index between the first light guide member 45 and the surrounding medium. It can be said that the imaging device 1 has a waveguide structure in which light is to be guided through the first light guide member 45.

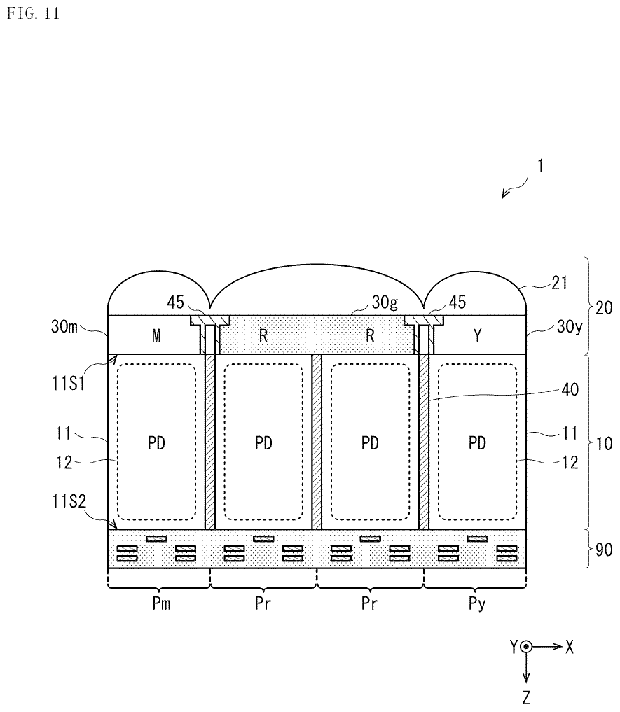

In the imaging device 1 according to the present modification example, the first light guide member 45 is provided, which makes it possible to reduce the occurrence of mixing of colors due to leakage of light to a surrounding pixel. Moreover, the first light guide member 45 enables propagating incoming light toward the photoelectric converter 12, which makes it possible to improve sensitivity to incoming light. It is to be noted that the first light guide member 45 is not limited in shape to a particular one and it may have, for example, a T-shape as illustrated in FIG. 11.

### 2-4. Modification Example 4

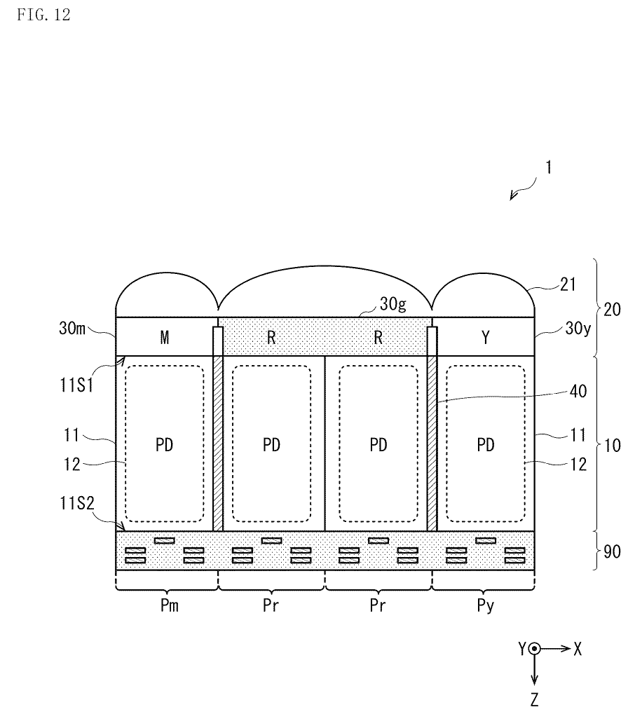

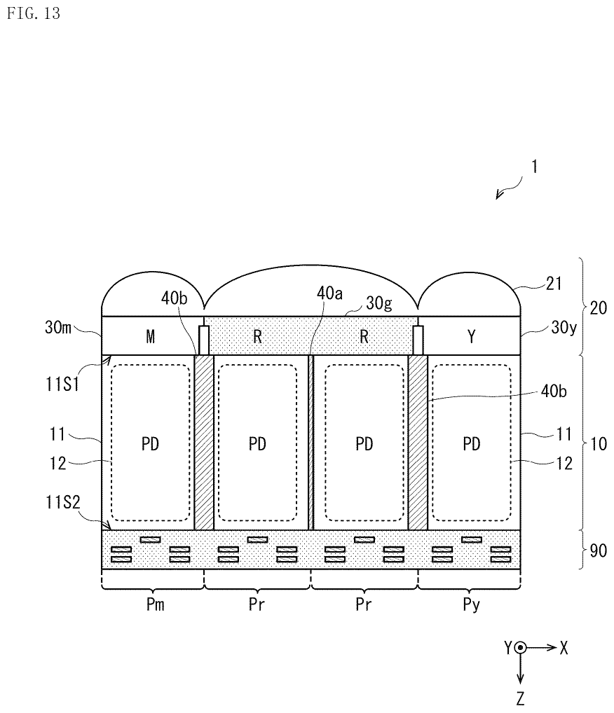

Although the arrangement example of the separator 40 is described in the above-described embodiment, the arrangement of the separator 40 is not limited thereto. For example, as illustrated in FIG. 12, no separator 40 may be provided between pixels of the same color (in FIG. 12, between adjacent ones of the pixels Pr). Moreover, for example, as illustrated in FIG. 13, a relatively thick separator 40b may be arranged between pixels of different colors to reduce mixing of colors, while a relatively thin separator 40a may be arranged between pixels of the same color. A width of the separator 40b is larger than a width of the separator 40a.

### 2-5. Modification Example 5

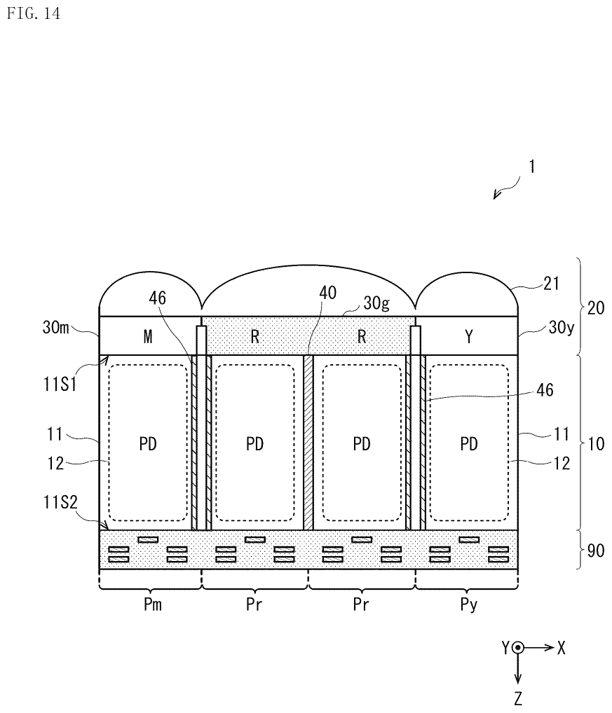

FIG. 14 is a diagram illustrating an example of a cross-sectional configuration of an imaging device according to Modification Example 5. The imaging device 1 includes a second light guide member 46 provided between pixels of different colors. The second light guide member 46 has a lower refractive index than a surrounding medium. The second light guide member 46, for example, includes an oxide film or has a void (a gap). The second light guide member 46 has a trench structure provided between adjacent ones of the photoelectric converters 12 and at a boundary between adjacent ones of the pixels P. The second light guide member 46 may be formed to reach the second surface 11S2 of the semiconductor substrate 11 as illustrated in FIG. 14. In the present modification example, the second light guide member 46 is provided, which makes it possible to reduce the occurrence of mixing of colors due to leakage of light to a surrounding pixel.

### 2-6. Modification Example 6

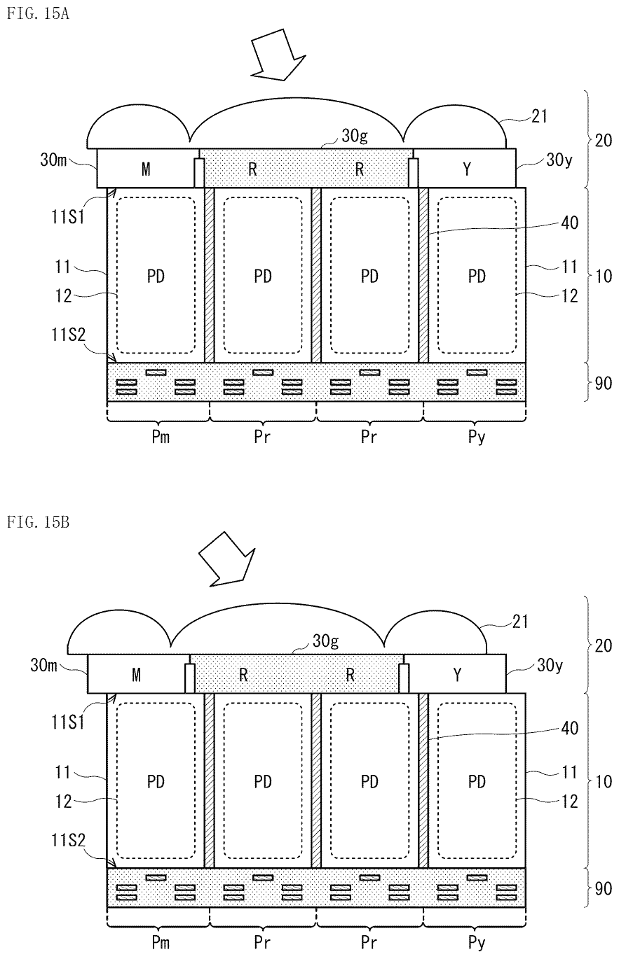

FIG. 15A illustrates an example of a cross-sectional configuration of an imaging device at a position at a first distance from a center of the pixel section, that is, in a region at a first image height. FIG. 15B illustrates an example of a cross-sectional configuration of the imaging device at a position at a second distance from the center of the pixel section, that is, in a region at a second image height. Here, the second distance, that is, the second image height, is larger than the first distance, that is, the first image height.

Light from the optical lens 101 almost vertically enters a middle portion of the pixel section 110 of the imaging device 1. In contrast, light obliquely enters a peripheral portion located at an outer side with respect to the middle portion, that is, in a region distant from a middle of the pixel section 110, as examples depicted by open arrows in FIG. 15A and FIG. 15B. Accordingly, in the present modification example, positions of the lens section 21 and the color filter 30 of each of the pixels P differ in accordance with a distance from the center of the pixel section 110 (the light receiver 10), that is, image height.

As illustrated in FIG. 15A, the lens section 21 and the color filter 30 of each of the pixels P are disposed to be offset toward the middle of the pixel section 110 (the light receiver 10) with respect to the photoelectric converter 12 of the pixel P. In the example illustrated in FIG. 15B, the lens section 21 and the color filter 30 of each of the pixels P are disposed to be offset toward the middle of the pixel section 110 with respect to the photoelectric converter 12 of the pixel P by a larger offset amount than in the case of FIG. 15A. It is to be noted that the pixels P are configured, for example, as illustrated in FIG. 6 in a middle region of the pixel section 110.

As seen from the above, the respective positions of the lens section 21 and the color filter 30 are adjusted in accordance with image height in the present modification example, which makes it possible to suitably perform pupil correction. This makes it possible to reduce a decrease in the amount of light entering the photoelectric converter 12 to prevent a decrease in sensitivity to incoming light.

### 3. Practical Application Example

### Example of Practical Application to Mobile Body

The technique according to the present disclosure (the present technology) is applicable to various products. For example, the technique according to the present disclosure may be implemented as an apparatus to be mounted on any kind of mobile bodies, e.g., an automobile, an electric automobile, a hybrid electric automobile, a motorcycle, a bicycle, personal mobility, an aircraft, a drone, a vessel, and a robot.

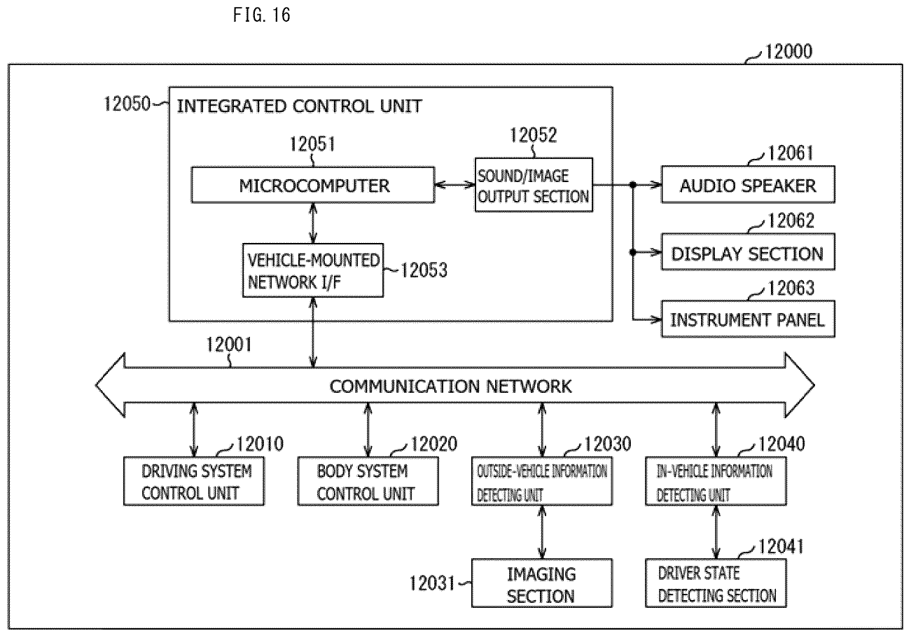

FIG. 16 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 16, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 16, an audio speaker 12061, a display section 12062, and an instrument panel 12063 are illustrated as the output device. The display section 12062 may, for example, include at least one of an on-board display and a head-up display.

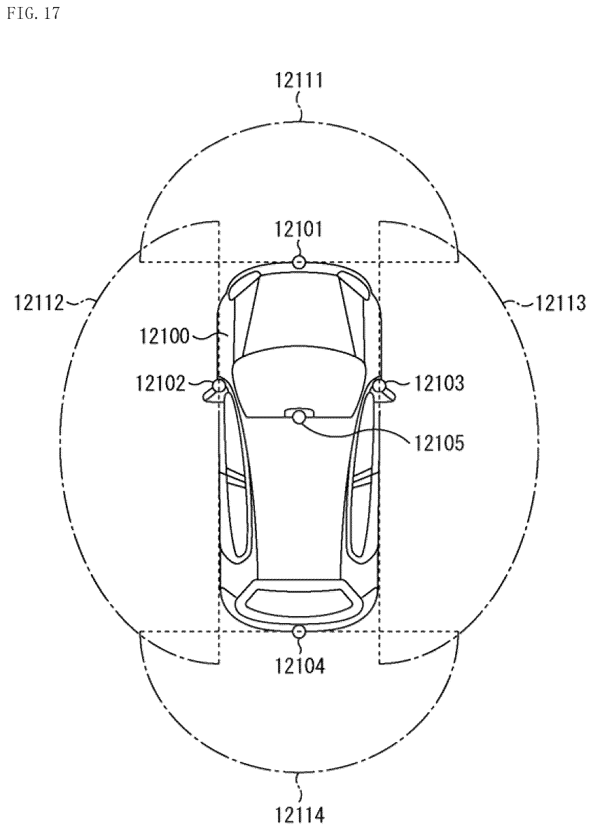

FIG. 17 is a diagram depicting an example of the installation position of the imaging section 12031.

In FIG. 17, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 17 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the forgoing, described is one example of the mobile body control system to which the technique according to the present disclosure may be applied. The technique according to the present disclosure may be applied to, for example, the imaging section 12031 out of the components as described above. Specifically, for example, the imaging device 1 and the electronic apparatus 100 are usable in the imaging section 12031. Application of the technique according to the present disclosure to the imaging section 12031 makes it possible to obtain a high-definition photographed image, enabling the mobile body control system to perform a highly accurate control using the photographed image.

### Example of Practical Application to Endoscopic Surgery System

The technique according to the present disclosure (the present technology) is applicable to various products. The technique according to the present disclosure may be applied to, for example, an endoscopic surgery system.

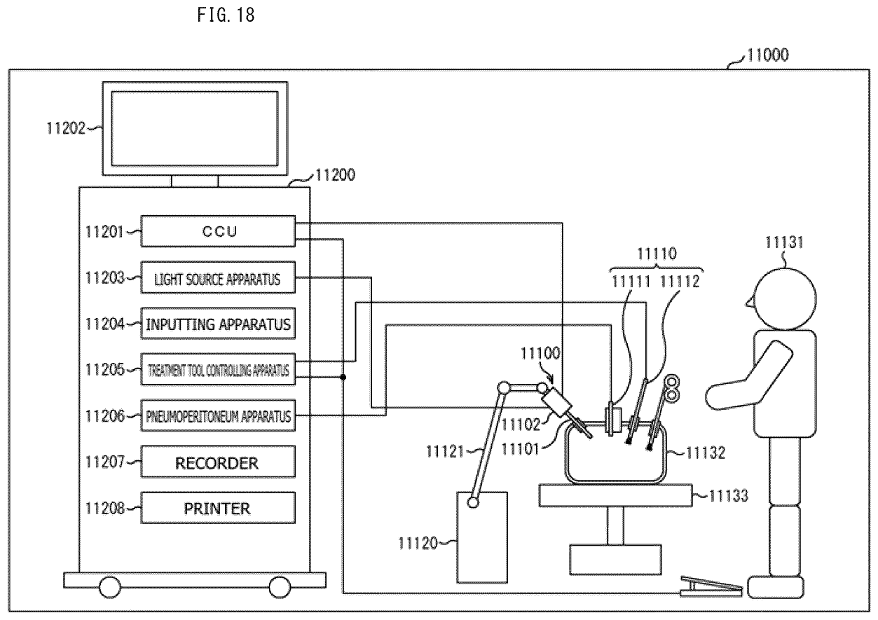

FIG. 18 is a view depicting an example of a schematic configuration of an endoscopic surgery system to which the technology according to an embodiment of the present disclosure (present technology) can be applied.

In FIG. 18, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

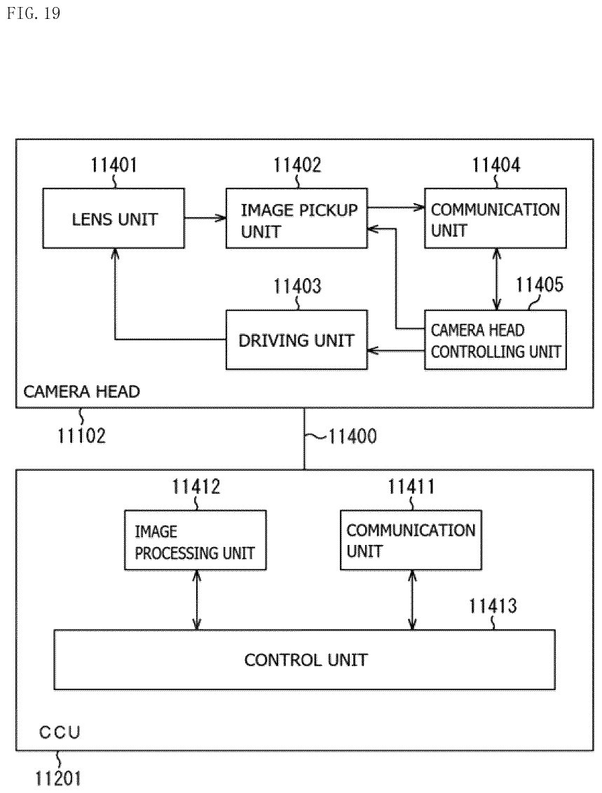

FIG. 19 is a block diagram depicting an example of a functional configuration of the camera head 11102 and the CCU 11201 depicted in FIG. 18.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

In the forgoing, described is one example of the endoscopic surgery system to which the technique according to the present disclosure may be applied. The technique according to the present disclosure may be favorably applied to, for example, the image pickup unit 11402 provided in the camera head 11102 of the endoscope 11100 out of the components as described above. Application of the technique according to the present disclosure enables the image pickup unit 11402 to be highly sensitized to provide the high-definition endoscope 11100.

Although description has been made on the present disclosure by giving the embodiment, the modification examples, the application examples, and the practical application examples as described above, the present technology is not limited to the above-described embodiment and the like may be modified in a variety of ways. For example, although the above-described modification examples are explained as modification examples of the above-described embodiment, the configurations of the modification examples may be combined as appropriate. For example, the present disclosure is not limited to a back-illuminated image sensor and may be applied to a front-illuminated image sensor.

An imaging device according to an embodiment of the present disclosure includes: a first pixel including a first filter that transmits light of a first wavelength and a first photoelectric converter; a second pixel including a second filter that transmits light of a second wavelength and a second photoelectric converter; a third pixel including a third filter that transmits light of a third wavelength and a third photoelectric converter; a fourth pixel including a fourth filter that transmits light of the second wavelength and light of the third wavelength and a fourth photoelectric converter; a fifth pixel including a fifth filter that transmits light of the first wavelength and light of the third wavelength and a fifth photoelectric converter; and a sixth pixel including a sixth filter that transmits light of the first wavelength and light of the second wavelength and a sixth photoelectric converter. This makes it possible to obtain pixel signals of RGB and pixel signals of CMY. Both an RGB image and a CMY image are obtainable by performing imaging once to enable a high color reproducibility.

It is to be noted that effects described herein are merely examples and the descriptions thereof are not limiting. Accordingly, another effect may be possible. Moreover, the present disclosure may have the following configuration.

(1)

An imaging device including:
a first pixel including a first filter that transmits light of a first wavelength and a first photoelectric converter;
a second pixel including a second filter that transmits light of a second wavelength and a second photoelectric converter;
a third pixel including a third filter that transmits light of a third wavelength and a third photoelectric converter;
a fourth pixel including a fourth filter that transmits light of the second wavelength and light of the third wavelength and a fourth photoelectric converter;
a fifth pixel including a fifth filter that transmits light of the first wavelength and light of the third wavelength and a fifth photoelectric converter; and
a sixth pixel including a sixth filter that transmits light of the first wavelength and light of the second wavelength and a sixth photoelectric converter.
   (2)

The imaging device (1), in which
the first filter transmits, as the light of the first wavelength, light of a wavelength band of red,
the second filter transmits, as the light of the second wavelength, light of a wavelength band of green, and
the third filter transmits, as the light of the third wavelength, light of a wavelength band of blue.
   (3)

The imaging device according to (1) or (2), in which
the fourth filter transmits light of a wavelength band of cyan,
the fifth filter transmits light of a wavelength band of magenta, and
the sixth filter transmits light of a wavelength band of yellow.
   (4)

The imaging device according to any one of (1) to (3), in which
the first photoelectric converter photoelectrically converts the light transmitted through the first filter,
the second photoelectric converter photoelectrically converts the light transmitted through the second filter,
the third photoelectric converter photoelectrically converts the light transmitted through the third filter,
the fourth photoelectric converter photoelectrically converts the light transmitted through the fourth filter,
the fifth photoelectric converter photoelectrically converts the light transmitted through the fifth filter, and
the sixth photoelectric converter photoelectrically converts the light transmitted through the sixth filter.
   (5)

The imaging device according to any one of (1) to (4), further including a first lens provided with respect to four of the first pixels, in which
the first photoelectric converters of the four first pixels photoelectrically convert light transmitted through the first lens and the respective first filters.
   (6)

The imaging device according to any one of (1) to (5), further including:
a second lens provided with respect to four of the second pixels; and
a third lens provided with respect to four of the third pixels, in which
the second photoelectric converters of the four second pixels photoelectrically convert light transmitted through the second lens and the respective second filters, and
the third photoelectric converters of the four third pixels photoelectrically convert light transmitted through the third lens and the respective third filters.
   (7)

The imaging device according to any one of (1) to (6), further including:
a fourth lens provided with respect to the fourth pixel;
a fifth lens provided with respect to the fifth pixel; and
a sixth lens provided with respect to the sixth pixel.
   (8)

The imaging device according to any one of (1) to (7), in which
6 by 6 pixels are repeatedly arranged, the 6 by 6 pixels including a plurality of the first pixels, a plurality of the second pixels, a plurality of the third pixels, a plurality of the fourth pixels, a plurality of fifth pixels, and a plurality of the sixth pixels.
   (9)

The imaging device according to any one of (1) to (8), in which
each of the plurality of fourth pixels, the plurality of fifth pixels, and the plurality of sixth pixels is disposed in a cross shape.
   (10)

The imaging device according to any one of (1) to (4), further including a fourth lens provided with respect to four of the fourth pixels, in which
the fourth photoelectric converters of the four fourth pixels photoelectrically convert light transmitted through the fourth lens and the respective fourth filters.
   (11)

The imaging device according to (10), further including:
a fifth lens provided with respect to four of the fifth pixels; and
a sixth lens provided with respect to four of the sixth pixels, in which
the fifth photoelectric converters of the four fifth pixels photoelectrically convert light transmitted through the fifth lens and the respective fifth filters, and
the sixth photoelectric converters of the four sixth pixels photoelectrically convert light transmitted through the sixth lens and the respective sixth filters.
   (12)

The imaging device according to (10) or (11), further including:
a first lens provided with respect to the first pixel;
a second lens provided with respect to the second pixel; and
a third lens provided with respect to the third pixel.
   (13)

The imaging device according to any one of (10) to (12), in which
6 by 6 pixels are repeatedly arranged, the 6 by 6 pixels including a plurality of the first pixels, a plurality of the second pixels, a plurality of the third pixels, a plurality of the fourth pixels, a plurality of fifth pixels, and a plurality of the sixth pixels.
   (14)

The imaging device according to any one of (10) to (13), in which each of the plurality of first pixels, the plurality of second pixels, and the plurality of third pixels is disposed in a cross shape.

(15)

An electronic apparatus including:
an imaging device including
   a first pixel including a first filter that transmits light of a first wavelength and a first photoelectric converter,
   a second pixel including a second filter that transmits light of a second wavelength and a second photoelectric converter,
   a third pixel including a third filter that transmits light of a third wavelength and a third photoelectric converter,
   a fourth pixel including a fourth filter that transmits light of the second wavelength and light of the third wavelength and a fourth photoelectric converter,
   a fifth pixel including a fifth filter that transmits light of the first wavelength and light of the third wavelength and a fifth photoelectric converter, and
   a sixth pixel including a sixth filter that transmits light of the first wavelength and light of the second wavelength and a sixth photoelectric converter; and
a signal processing section that performs signal processing on a signal outputted from the imaging device.

The present application claims the benefit of Japanese Priority Patent Application JP2022-001095 filed with the Japan Patent Office on Jan. 6, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An imaging device, comprising:
a first pixel including a first filter that transmits light of a first wavelength and a first photoelectric converter;
a second pixel including a second filter that transmits light of a second wavelength and a second photoelectric converter;
a third pixel including a third filter that transmits light of a third wavelength and a third photoelectric converter;
a fourth pixel including a fourth filter that transmits light of the second wavelength and light of the third wavelength and a fourth photoelectric converter;
a fifth pixel including a fifth filter that transmits light of the first wavelength and light of the third wavelength and a fifth photoelectric converter; and
a sixth pixel including a sixth filter that transmits light of the first wavelength and light of the second wavelength and a sixth photoelectric converter.

2. The imaging device according to claim 1, wherein
the first filter transmits, as the light of the first wavelength, light of a wavelength band of red,
the second filter transmits, as the light of the second wavelength, light of a wavelength band of green, and
the third filter transmits, as the light of the third wavelength, light of a wavelength band of blue.

3. The imaging device according to claim 2, wherein
the fourth filter transmits light of a wavelength band of cyan,
the fifth filter transmits light of a wavelength band of magenta, and
the sixth filter transmits light of a wavelength band of yellow.

4. The imaging device according to claim 1, wherein
the first photoelectric converter photoelectrically converts the light transmitted through the first filter,
the second photoelectric converter photoelectrically converts the light transmitted through the second filter,
the third photoelectric converter photoelectrically converts the light transmitted through the third filter,
the fourth photoelectric converter photoelectrically converts the light transmitted through the fourth filter,
the fifth photoelectric converter photoelectrically converts the light transmitted through the fifth filter, and
the sixth photoelectric converter photoelectrically converts the light transmitted through the sixth filter.

5. The imaging device according to claim 1, further comprising a first lens provided with respect to four of the first pixels, wherein
the first photoelectric converters of the four first pixels photoelectrically convert light transmitted through the first lens and the respective first filters.

6. The imaging device according to claim 5, further comprising:
a second lens provided with respect to four of the second pixels; and
a third lens provided with respect to four of the third pixels, wherein
the second photoelectric converters of the four second pixels photoelectrically convert light transmitted through the second lens and the respective second filters, and
the third photoelectric converters of the four third pixels photoelectrically convert light transmitted through the third lens and the respective third filters.

7. The imaging device according to claim 6, further comprising:
a fourth lens provided with respect to the fourth pixel;
a fifth lens provided with respect to the fifth pixel; and
a sixth lens provided with respect to the sixth pixel.

8. The imaging device according to claim 7, wherein
6 by 6 pixels are repeatedly arranged, the 6 by 6 pixels including a plurality of the first pixels, a plurality of the second pixels, a plurality of the third pixels, a plurality of the fourth pixels, a plurality of fifth pixels, and a plurality of the sixth pixels.

9. The imaging device according to claim 8, wherein
each of the plurality of fourth pixels, the plurality of fifth pixels, and the plurality of sixth pixels is disposed in a cross shape.

10. The imaging device according to claim 1, further comprising a fourth lens provided with respect to four of the fourth pixels, wherein
the fourth photoelectric converters of the four fourth pixels photoelectrically convert light transmitted through the fourth lens and the respective fourth filters.

11. The imaging device according to claim 10, further comprising:
a fifth lens provided with respect to four of the fifth pixels; and
a sixth lens provided with respect to four of the sixth pixels, wherein
the fifth photoelectric converters of the four fifth pixels photoelectrically convert light transmitted through the fifth lens and the respective fifth filters, and
the sixth photoelectric converters of the four sixth pixels photoelectrically convert light transmitted through the sixth lens and the respective sixth filters.

12. The imaging device according to claim 11, further comprising:
a first lens provided with respect to the first pixel;
a second lens provided with respect to the second pixel; and
a third lens provided with respect to the third pixel.

13. The imaging device according to claim 12, wherein
6 by 6 pixels are repeatedly arranged, the 6 by 6 pixels including a plurality of the first pixels, a plurality of the second pixels, a plurality of the third pixels, a plurality of the fourth pixels, a plurality of fifth pixels, and a plurality of the sixth pixels.

14. The imaging device according to claim 13, wherein
each of the plurality of first pixels, the plurality of second pixels, and the plurality of third pixels is disposed in a cross shape.

15. An electronic apparatus, comprising:
an imaging device including
a first pixel including a first filter that transmits light of a first wavelength and a first photoelectric converter,
a second pixel including a second filter that transmits light of a second wavelength and a second photoelectric converter,
a third pixel including a third filter that transmits light of a third wavelength and a third photoelectric converter,
a fourth pixel including a fourth filter that transmits light of the second wavelength and light of the third wavelength and a fourth photoelectric converter,
a fifth pixel including a fifth filter that transmits light of the first wavelength and light of the third wavelength and a fifth photoelectric converter, and
a sixth pixel including a sixth filter that transmits light of the first wavelength and light of the second wavelength and a sixth photoelectric converter; and
a signal processing section that performs signal processing on a signal outputted from the imaging device.
